(19) United States
(12) Patent Application Publication
(10) Pub. No.: US 2026/0047486 A1
(43) Pub. Date: Feb. 12, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Chih-Chiang HE, Taichung City (TW); Chia Chen CHIAO, Taichung City (TW)

(21) Appl. No.: 19/004,805

(22) Filed: Dec. 30, 2024

(30) Foreign Application Priority Data
Aug. 12, 2024 (TW) 113130176

(51) Int. Cl. H01L 25/16; G02B 6/42; H01L 21/56; H01L 23/00; H01L 23/31; H01L 23/498; H10B 80/00; H10D 80/30

(52) U.S. Cl. CPC H01L 25/167; G02B 6/4239; H01L 21/56; H01L 23/3157; H10D 80/30; H01L 23/49816; H01L 24/16; H01L 2224/16227; H01L 2224/16238; H01L 2924/1903; H10B 80/00

(57) ABSTRACT

An electronic package and a manufacturing method thereof are provided. A semiconductor component and an optoelectronic component are provided on a carrier structure. The optoelectronic component is covered with a shielding layer, and an encapsulation layer is formed to cover the semiconductor component and the optoelectronic component. The shielding layer is removed to expose the optoelectronic component, allowing subsequent connection of an optical device on the optoelectronic component. The process of the Co-packaged optics module is simplified.

### CROSS-REFERENCE TO RELATED APPLICATIONS

The present application is based upon and claims the right of priority to TW Patent application Ser. No. 11/313,0176, filed Aug. 12, 2024, the disclosure of which is hereby incorporated by reference herein in its entirety for all purposes

### BACKGROUND

### 1. Technical Field

The present disclosure relates to a semiconductor device, and more particularly, to a semiconductor device with an optoelectronic component and a manufacturing method thereof.

### 2. Description of Related Art

With the vigorous development of the electronic industry, electronic products are gradually moving towards multi-function and high performance. The current applications of the fifth generation (5G) communication technology have expanded to the Internet of Things (IoT), Industrial Internet of Things (IIoT), cloud, artificial intelligence (AI), autonomous car, and medical, among others. Additionally, with the expansion of the application level, a large amount of data is generated that requires efficient transmission, computation and storage, especially requirements for data transmission requirements has emerged in large numbers, causing the industry to begin to employ “light” instead of “electricity” as the carrier of data transmission, thereby improving transmission capacity, efficiency or distance, and reducing energy consumption during the transmission process. Under this background, silicon photonics components and application products thereof, as well as Co-Packaged optics (CPO) modules, have become the development trend of future semiconductor and packaging technology.

The CPO module mainly integrates an electronic integrated circuit (EIC) component and a photonic integrated circuit (PIC) component into one package. The EIC is designed to be packaged similarly to traditional logic chips and can be covered directly with the encapsulant. However, the PIC transmits optical signals and needs connection to an external optical device, requiring special consideration in the packaging design. As a result, the process of the CPO module is too cumbersome, not only slowing down the process, but also failing to maintain or improve the yield, making it impossible to reduce manufacturing costs.

Therefore, there is a need for a solution that addresses the aforementioned shortcomings in the prior art.

### SUMMARY

In view of the aforementioned shortcomings of the prior art, the present disclosure provides an electronic package, comprising: a carrier structure; a semiconductor component disposed on the carrier structure and electrically connected to the carrier structure, wherein the semiconductor component has an active surface and a non-active surface opposite to the active surface, and is provided on the carrier structure via the active surface; an optoelectronic component disposed on the carrier structure and electrically connected to the carrier structure, wherein the optoelectronic component has an optically active surface and an attachment surface opposite to the optically active surface, and is provided on the carrier structure via the attachment surface; and an encapsulation layer formed on the carrier structure to cover the semiconductor component and the optoelectronic component, with the optically active surface exposed from the encapsulation layer, wherein a height exists difference between an upper surface of the encapsulation layer and the optically active surface of the optoelectronic component.

The present disclosure further provides a method of manufacturing an electronic package, comprising: disposing a semiconductor component and an optoelectronic component on a first side of a carrier structure, wherein the semiconductor component has an active surface and a non-active surface opposite to the active surface and is provided on the carrier structure via the active surface, and the optoelectronic component has an optically active surface and an attachment surface opposite to the optically active surface and is provided on the carrier structure via the attachment surface; forming a shielding layer on the optically active surface; forming an encapsulation layer on the carrier structure to cover the semiconductor component, the optoelectronic component and the shielding layer, with the shielding layer exposed from the encapsulation layer; and removing the shielding layer to expose the optically active surface of the optoelectronic component, allowing a height difference exist between an upper surface of the encapsulation layer and the optically active surface of the optoelectronic component.

In the aforementioned electronic package and manufacturing method thereof, the semiconductor component is an electronic IC.

In the aforementioned electronic package and manufacturing method thereof, the optoelectronic component is a photonic IC.

In the aforementioned electronic package and manufacturing method thereof, the electronic package further comprises an electronic component disposed on the carrier structure and electrically connected to the carrier structure.

In the aforementioned electronic package and manufacturing method thereof, the non-active surface of the semiconductor component is exposed from the encapsulation layer.

In the aforementioned electronic package and manufacturing method thereof, the upper surface of the encapsulation layer is flush with the non-active surface of the semiconductor component.

In the aforementioned electronic package and manufacturing method thereof, the height difference is 10 μm to 20 μm.

In the aforementioned electronic package and manufacturing method thereof, the encapsulation layer is formed with an opening for exposing the optically active surface, and a planar dimension of the opening is selected to be larger or smaller than a planar dimension of the optoelectronic component.

In the aforementioned electronic package and manufacturing method thereof, a center position of the opening of the encapsulation layer is offset from a center position of the optoelectronic component by a distance.

In the aforementioned electronic package and manufacturing method thereof, the electronic package further comprises an optical device disposed on the optoelectronic component. The optical device is an optical fiber array unit connected to an optical fiber.

In the aforementioned electronic package and manufacturing method thereof, the carrier structure has a first side and a second side opposite to the first side, the first side is provided with the semiconductor component and the optoelectronic component, and the second side is provided with a plurality of conductive components.

As can be seen from the above, in the electronic package and manufacturing method thereof of the present disclosure, a semiconductor component and an optoelectronic component are disposed on a carrier structure, and an optically active surface of the optoelectronic component is covered with a shielding layer, an encapsulation layer is formed to cover the semiconductor component and the optoelectronic component, the shielding layer is removed to expose the optically active surface, for subsequent connection of an optical device (e.g., an optical fiber). The encapsulation layer covers the semiconductor component and the optoelectronic component can be formed using a traditional encapsulant. Meanwhile, the encapsulation layer can be formed with an opening for exposing the optically active surface by removing the shielding layer that is previously disposed on the optoelectronic component, allowing connection to an external optical device, thereby simplifying the process of CPO module and further reducing process costs and improving process yield.

### BRIEF DESCRIPTION OF THE DRAWINGS

FIG. 1A to FIG. 1D are schematic cross-sectional views showing a method of manufacturing an electronic package according to the present disclosure.

FIG. 1E is a schematic top view showing an electronic package according to a first embodiment the present disclosure.

FIG. 2 is a schematic cross-sectional view showing an electronic package according to a second embodiment of the present disclosure.

FIG. 3A and FIG. 3B are schematic a cross-sectional view and a top view showing an electronic package according to a third embodiment of the present disclosure.

FIG. 4 is a schematic cross-sectional view showing an electronic package according to a fourth embodiment of the present disclosure.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “third” “a,” and the like are for illustrative purposes, and are not meant to limit the scope implementable by the present disclosure. Any changes or adjustments made to the relative relationships, without substantially modifying the technical contents, are also to be construed as within the scope implementable by the present disclosure.

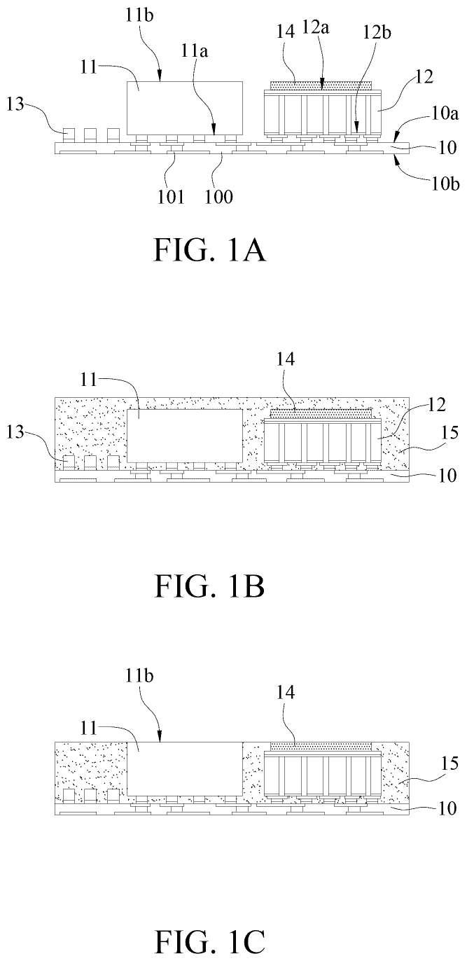

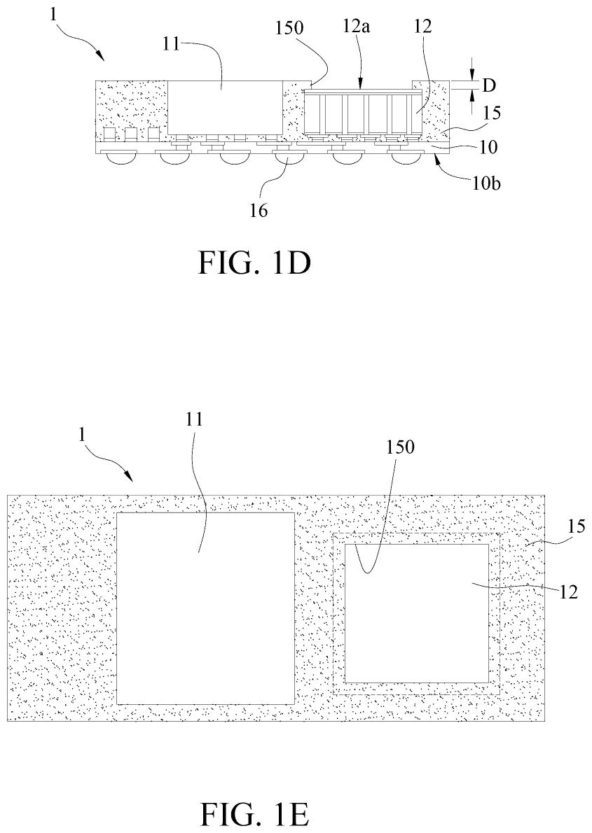

FIG. 1A to FIG. 1D are schematic cross-sectional views showing a method of manufacturing an electronic package 1 according to the present disclosure.

As shown in FIG. 1A, a carrier structure 10 is firstly provided, and the carrier structure 10 has a first side 10a and a second side 10b opposite to the first side 10a.

The carrier structure 10 can be a redistribution layer (RDL) structure or a semiconductor package substrate. In one embodiment, the carrier structure 10 is a semiconductor package substrate, which includes at least an insulating layer 100 and at least a circuit layer 101 bonded to the insulating layer 100. It should be understood that the carrier structure 10 may also be another board, such as a lead frame, an interposer board, a wafer, or any other carrier with metal routing, but not limited to the above.

Then, a semiconductor component 11, an optoelectronic component 12, and an electronic component 13 are disposed on the first side 10a of the carrier structure 10. Additionally, the semiconductor component 11, the optoelectronic component 12, and the electronic component 13 are electrically connected to the carrier structure 10.

The semiconductor component 11 can be a variety of active component or passive component. In one embodiment, the semiconductor component 11 is an electronic IC (EIC), but not limited to this.

The semiconductor component 11 has an active surface 11a and a non-active surface 11b opposite to the active surface 11a, and the semiconductor component 11 is provided on the carrier structure 10 via the active surface 11a.

The optoelectronic component 12 can be a photoelectric converter, an optical signal receiver, an optical signal transmitter, or a photonic IC (PIC) that meets functional requirements. In one embodiment, The optoelectronic component 12 is a photonic IC, but not limited to this.

The optoelectronic component 12 has an optically active surface 12a and an attachment surface 12b opposite to the optically active surface 12a, and is provided on the carrier structure 10 via the attachment surface 12b. Meanwhile, a shielding layer 14 is formed on the optically active surface 12a to cover at least part of the optically active surface 12a. The shielding layer 14 is a polymer organic silicon compound, such as polydimethylsiloxane (PDMS).

The electronic component 13 may be an active component, such as a switch chip, a high bandwidth memory (HBM) chip or other functional chips, or it may be a passive component such as a resistor, a capacitor, or an inductor. As long as a component is capable of meeting the designed functional requirements, there is no limitation in the present disclosure.

As shown in FIG. 1B, an encapsulation layer 15 is formed on the carrier structure 10 to cover the semiconductor component 11, the optoelectronic component 12, the electronic component 13, and the shielding layer 14. The encapsulation layer 15 is, for example, an encapsulant.

As shown in FIG. 1C, a thinning process is performed. Part of the encapsulation layer 15 (even part of the shielding layer 14) is removed by, for example, grinding, such that the non-active surface 11b of the semiconductor component 11 and the shielding layer 14 are exposed from the encapsulation layer 15, wherein the non-active surface 11b is flush with (i.e., coplanar with) the upper surface of the encapsulation layer 15. By exposing the non-active surface 11b of the semiconductor component 11 from the encapsulation layer 15, the heat dissipation effect of the semiconductor component 11 can be improved.

As shown in FIG. 1D, at least part of the optically active surface 12a of the optoelectronic component 12 is exposed by removing the shielding layer 14 through, for example, tape adhesion, for subsequent connection to an optical device (not shown). Additionally, a plurality of conductive components 16 are disposed on the second side 10b of the carrier structure 10 to prepare the electronic package 1 of the present disclosure.

Due to the removal of the shielding layer 14, a height difference D occurs between the upper surface of the encapsulation layer 15 and the optically active surface 12a of the optoelectronic component 12. That is, the upper surface of the encapsulation layer 15 is not flush with (coplanar with) the optically active surface 12a of the optoelectronic component 12, thereby reducing the damage to the optically active surface 12a. Moreover, the height difference D, which is about 10 μm to 20 μm (micrometers), between the upper surface of the encapsulation layer 15 and the optically active surface 12a of the optoelectronic component 12, can avoid alignment problems that may arise when bonding optical devices in subsequent states.

Please refer to FIG. 1E, the encapsulation layer 15 is formed with an opening 150 due to the removal of the shielding layer 14, wherein the planar dimension of the opening 150 is smaller than the planar dimension of the optoelectronic component 12 (the optically active surface 12a).

By means of the aforementioned method, the electronic package 1 is manufactured to include: a carrier structure 10; a semiconductor component 11 provided on and electrically connected to the carrier structure 10; an optoelectronic component 12 provided on and electrically connected to the carrier structure 10, wherein the optoelectronic component 12 has an optically active surface 12a and an attachment surface 12b opposite to the optically active surface 12a and is provided on the carrier structure 10 via the attachment surface 12b; and an encapsulation layer 15 formed on the carrier structure 10 to cover the semiconductor component 11 and the optoelectronic component 12, with the optically active surface 12a exposed from the encapsulation layer 15, wherein a height difference exists between an upper surface of the encapsulation layer and the optically active surface of the optoelectronic component.

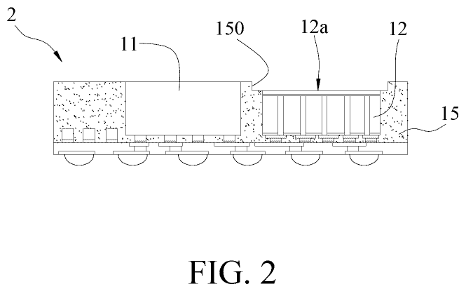

Please refer to FIG. 2, which is a schematic cross-sectional view showing an electronic package 2 according to a second embodiment of the present disclosure.

This embodiment is substantially the same as the aforementioned embodiment. The main difference is that the planar dimension of the shielding layer 14 covering the optoelectronic component 12 is larger than the planar dimension of the optoelectronic component 12. As a result, when the encapsulation layer 15 is subsequently formed and the shielding layer 14 is removed, the planar dimension of the opening 150 of the encapsulation layer 15 is larger than the planar dimension of the optoelectronic component 12 (the optically active surface 12a).

In an embodiment, the planar dimension of the opening 150 of the encapsulation layer 15 may be selected to be larger than or smaller than the planar dimension of the optoelectronic component 12, depending on the dimension of the optical device (not shown) to be bonded. For example, in one embodiment, if the opening 150 is larger, the coupling effect between the optical device and the optoelectronic component 12 is better. In another embodiment, if the opening 150 is smaller, the optical device is prone to be aligned with the optoelectronic component 12.

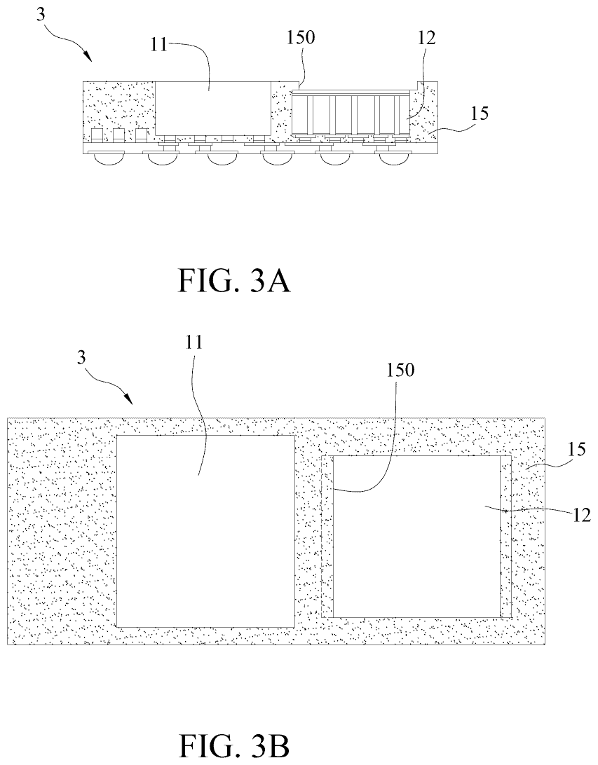

Please refer to FIG. 3A and FIG. 3B, which are schematic a cross-sectional view and a planar view showing an electronic package 3 according to a third embodiment of the present disclosure.

This embodiment is substantially the same as the aforementioned embodiment. The main difference is that the center position of the shielding layer 14, which previously covers the optoelectronic component 12, may be offset from the center position of the optoelectronic component 12 by a distance. Therefore, upon the subsequent formation of the encapsulation layer 15 and the removal of the shielding layer 14, the center position of the opening 150 of the encapsulation layer 15 may be offset from the center position of the optoelectronic component 12 by a distance, whereby the desired optical device is connected according to actual situation.

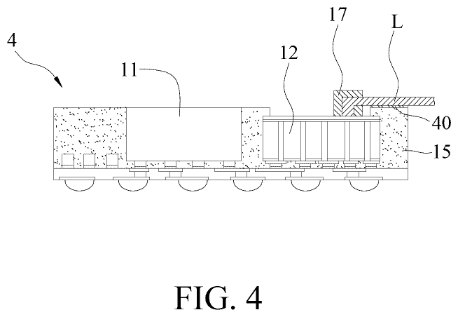

Please refer to FIG. 4, which is a schematic cross-sectional view showing an electronic package 4 according to a fourth embodiment of the present disclosure.

This embodiment is substantially the same as the aforementioned embodiment. The main difference is that the electronic package 4 further includes an optical device 17, such as a fiber array unit (FAU) connected to an optical fiber L, provided on the optoelectronic component 12, and that the optical fiber L may be provided on the encapsulation layer 15 through an adhesive layer 40.

To sum up, in the electronic package and manufacturing method thereof of the present disclosure, a semiconductor component and an optoelectronic component are provided on a carrier structure, and an optically active surface of the optoelectronic component is covered with a shielding layer, an encapsulation layer is formed to cover the semiconductor component and the optoelectronic component, and the shielding layer is removed to expose the optically active surface, for subsequent connection of an optical device (e.g., an optical fiber). The encapsulation layer covering the semiconductor component and the optoelectronic component can be formed using a traditional encapsulant. Meanwhile, the encapsulation layer can be formed with an opening for exposing the optically active surface by removing the shielding layer that is previously disposed on the optoelectronic component, allowing connection to an external optical device, thereby simplifying the process of CPO module and further reducing process costs and improving process yield.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
a semiconductor component having an active surface and a non-active surface opposite to the active surface, and provided on the carrier structure via the active surface and electrically connected to the carrier structure;
an optoelectronic component having an optically active surface and an attachment surface opposite to the optically active surface, and provided on the carrier structure via the attachment surface and electrically connected to the carrier structure; and
an encapsulation layer formed on the carrier structure to cover the semiconductor component and the optoelectronic component, with the optically active surface exposed from the encapsulation layer, wherein a height difference exists between an upper surface of the encapsulation layer and the optically active surface of the optoelectronic component.

2. The electronic package of claim 1, wherein the semiconductor component is an electronic IC.

3. The electronic package of claim 1, wherein the optoelectronic component is a photonic IC.

4. The electronic package of claim 1, further comprising an electronic component disposed on the carrier structure and electrically connected to the carrier structure.

5. The electronic package of claim 1, wherein the non-active surface of the semiconductor component is exposed from the encapsulation layer.

6. The electronic package of claim 1, wherein the upper surface of the encapsulation layer is flush with the non-active surface of the semiconductor component.

7. The electronic package of claim 1, wherein the height difference is 10 um to 20 um.

8. The electronic package of claim 1, wherein the encapsulation layer is formed with an opening for exposing the optically active surface, and a planar dimension of the opening is selected to be larger or smaller than a planar dimension of the optoelectronic component.

9. The electronic package of claim 8, wherein a center position of the opening of the encapsulation layer is offset from a center position of the optoelectronic component by a distance.

10. The electronic package of claim 1, further comprising an optical device disposed on the optoelectronic component.

11. The electronic package of claim 10, wherein the optical device is an optical fiber array unit connected to an optical fiber.

12. The electronic package of claim 1, wherein the carrier structure has a first side and a second side opposite to the first side, the first side is provided with the semiconductor component and the optoelectronic component, and the second side is provided with a plurality of conductive components.

13. A method of manufacturing an electronic package, the method comprising:
disposing a semiconductor component and an optoelectronic component on a first side of a carrier structure, wherein the semiconductor component has an active surface and a non-active surface opposite to the active surface and is provided on the carrier structure via the active surface, and the optoelectronic component has an optically active surface and an attachment surface opposite to the optically active surface and is provided on the carrier structure via the attachment surface;
forming a shielding layer on the optically active surface;
forming an encapsulation layer on the carrier structure to cover the semiconductor component, the optoelectronic component and the shielding layer, with the shielding layer exposed from the encapsulation layer; and
removing the shielding layer to expose the optically active surface of the optoelectronic component, allowing a height difference exist between an upper surface of the encapsulation layer and the optically active surface of the optoelectronic component.

14. The method of claim 13, wherein the semiconductor component is an electronic IC.

15. The method of claim 13, wherein the optoelectronic component is a photonic IC.

16. The method of claim 13, further comprising disposing an electronic component on the carrier structure and electrically connecting the electronic component to the carrier structure.

17. The method of claim 13, wherein the non-active surface of the semiconductor component is exposed from the encapsulation layer.

18. The method of claim 13, wherein the upper surface of the encapsulation layer is flush with the non-active surface of the semiconductor component.

19. The method of claim 13, wherein the height difference is 10 um to 20 um.

20. The method of claim 13, wherein the encapsulation layer is formed with an opening for exposing the optically active surface, and a planar dimension of the opening is selected to be larger or smaller than a planar dimension of the optoelectronic component.

21. The method of claim 20, wherein a center position of the opening of the encapsulation layer is offset from a center position of the optoelectronic component by a distance.

22. The method of claim 13, further comprising disposing an optical device on the optoelectronic component.

23. The method of claim 22, wherein the optical device is an optical fiber array unit connected to an optical fiber.

24. The method of claim 13, further comprising bonding a plurality of conductive components on a second side of the carrier structure.
